(19) United States
(12) Patent Application Publication
(10) Pub. No.: US 2023/0067667 A1
(43) Pub. Date: Mar. 2, 2023

(54) BIOSENSOR STRUCTURE, BIOSENSOR SYSTEM, AND METHOD FOR FORMING BIOSENSOR

(71) Applicant: VisEra Technologies Company Limited, Hsin-Chu City (TW)

(72) Inventors: Yi-Hua CHIU, Hsinchu City (TW); Hsin-Yi HSIEH, Taoyuan City (TW); Wei-Ko WANG, Taoyuan City (TW)

(21) Appl. No.: 17/461,003

(22) Filed: Aug. 30, 2021

(51) Int. Cl. G01N 27/327; H01L 21/306

(52) U.S. Cl. CPC G01N 27/327; H01L 21/30604; B82Y 20/00

(57) ABSTRACT

A biosensor structure is provided. The biosensor structure includes a substrate, an insulating layer, a semiconductor layer and a gold disc. The insulating layer is disposed on the substrate. The semiconductor layer is disposed on the insulating layer, and a well is disposed in the semiconductor layer. The gold disc is disposed at bottom of the well.

### BACKGROUND

### Technical Field

The present disclosure is related to a biosensor structure, a biosensor system, and a method of forming the biosensor structure. The present disclosure is related in particular to a biosensor structure and a biosensor system fabricated using a metal-assisted chemical etching (MacEtch) process.

### Description of the Related Art

Measurement reactions using a sophisticated biomolecule identification function such as an antigen-antibody, protein-protein, and protein-DNA, etc., are becoming important techniques in clinical testing and in taking measurements in the field of biochemistry. In addition, the analysis of DNA hybridization, or DNA sequencing is also extensively used in the research field of biochemistry.

Various biochips, such as microfluidic chips, micro-array chips, or lab-on-a-chip, have been developed for biological and chemical analysis. With the flourishing development of sensor devices, people have high expectations regarding the reliability, quality, and cost of these biochips.

Although existing biochips have generally been adequate for their intended purposes, they have not been entirely satisfactory in all respects. For example, the reaction wells of biochips are generally fabricated using a photolithography process. Nevertheless, it is difficult to minimize the critical dimension or increase the aspect ratio of the reaction wells due to the processing limit of photolithography (e.g., the size limitations on mask alignment, exposure, etc.).

### SUMMARY

In accordance with some embodiments of the present disclosure, a biosensor structure is provided. The biosensor structure includes a substrate, an insulating layer, a semiconductor layer and a gold disc. The insulating layer is disposed on the substrate. The semiconductor layer is disposed on the insulating layer, and a well is disposed in the semiconductor layer. The gold disc is disposed at bottom of the well.

In accordance with some embodiments of the present disclosure, a biosensor system is provided. The biosensor system includes a biosensor structure and a detector structure for detecting the biosensor structure. The biosensor structure includes a substrate, an insulating layer, a semiconductor layer and a gold disc. The insulating layer is disposed on the substrate. The semiconductor layer is disposed on the insulating layer, and a well is disposed in the semiconductor layer. The gold disc is disposed at bottom of the well.

In accordance with some embodiments of the present disclosure, a method for forming a biosensor structure is provided. The method includes the following steps. A substrate is provided. An insulating layer is formed on the substrate. A semiconductor layer is formed on the insulating layer. A gold disc is formed on a top surface of the semiconductor layer. A well is formed in the semiconductor layer using an etching process. The position of the well is defined by the location of the gold disc. The gold disc remains at the bottom of the well.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1A is a schematic diagram of a biosensor structure in accordance with some embodiments of the present disclosure;

FIG. 1B is a cross-sectional diagram of the biosensor structure taken along the section line A-A′ in FIG. 1A in accordance with some embodiments of the present disclosure;

FIGS. 2A-2D are a cross-sectional diagrams of a biosensor structure during a method for forming the biosensor structure in accordance with some embodiments of the present disclosure;

FIG. 3 is a cross-sectional diagram of the biosensor structure in accordance with some embodiments of the present disclosure.

### DETAILED DESCRIPTION

The biosensor structure, the biosensor system, and the method of forming the biosensor structure and the biosensor system according to the present disclosure are described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the concept of the present disclosure may be embodied in various forms without being limited to those exemplary embodiments. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments.

It should be understood that this description of the exemplary embodiments is intended to be read in connection with the accompanying drawings, which are to be considered part of the entire written description. The drawings may be not drawn to scale. In fact, the size of the element may be arbitrarily enlarged or reduced in order to clearly express the features of the present disclosure.

In addition, the expressions “a layer overlying another layer”, “a layer is disposed above another layer”, “a layer is disposed on another layer” and “a layer is disposed over another layer” may indicate that the layer is in direct contact with the other layer, or that the layer is not in direct contact with the other layer, there being one or more intermediate layers disposed between the layer and the other layer.

In addition, in this specification, relative expressions are used. For example, “lower”, “bottom”, “higher” or “top” are used to describe the position of one element relative to another. It should be appreciated that if a device is flipped upside down, an element that is “lower” will become an element that is “higher”.

It should be understood that, although the terms “first”, “second”, “third” etc. may be used herein to describe various elements, components, or portions, these elements, components, or portions should not be limited by these terms. These terms are only used to distinguish one element, component, or portion from another element, component, or portion. Thus, a first element, component, or portion discussed below could be termed a second element, component, or portion without departing from the teachings of the present disclosure.

The terms “about” and “substantially” typically mean +/−10% of the stated value, more typically mean +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about” or “substantially”. Furthermore, the phrase “in a range from a first value to a second value” indicates that the range includes the first value, the second value, and other values between them.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with some embodiments of the present disclosure, the wells of the biosensor structure are formed using a metal-assisted chemical etching (MacEtch) process, and the gold discs used to define the positions of the wells remain at the bottom of the well. The critical dimension of the wells of the biosensor structure formed by such a method can be reduced and the aspect ratio of the wells can be increased. Accordingly, the sensitivity and throughput of the biosensor structure can be improved. In addition, the gold discs have good performance on capture biosamples through self-assembly of gold-sulfur (Au—S) bonding. Therefore, further modification (e.g., immobilization of anchor molecules etc.) to the bottom of the wells where the gold discs are located may not be needed.

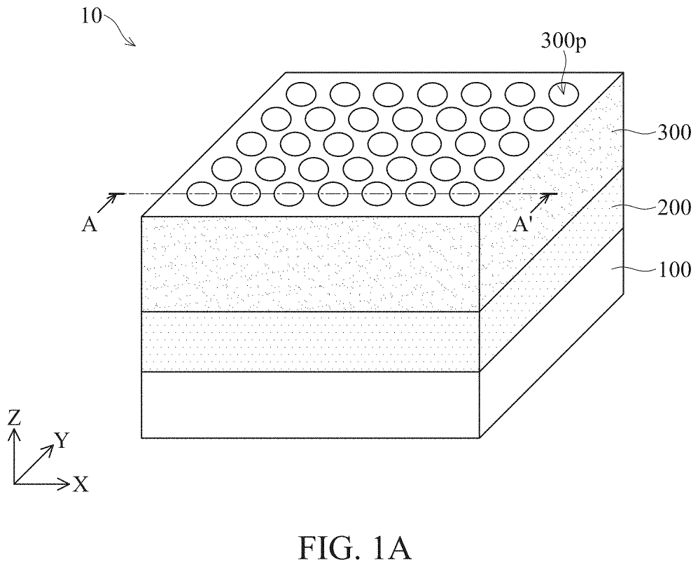

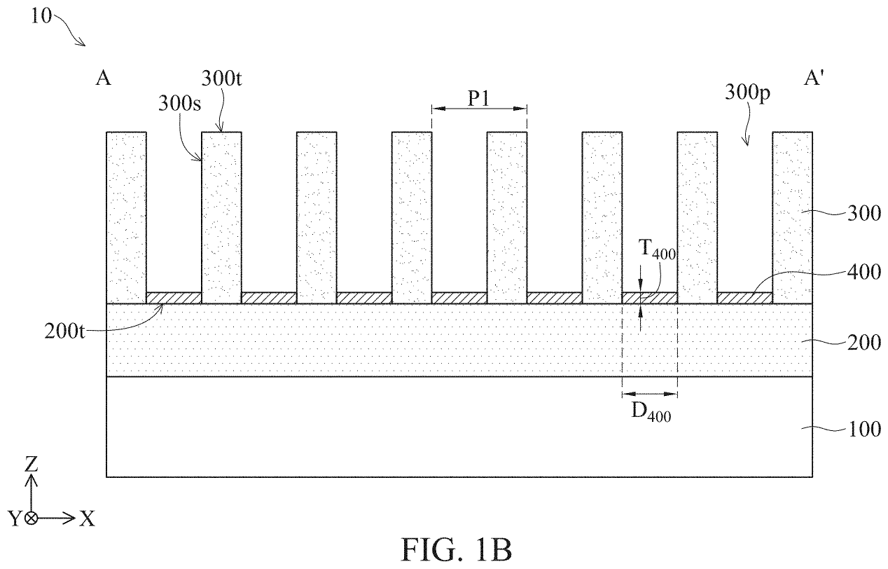

Refer to FIG. 1A and FIG. 1B. FIG. 1A is a schematic diagram of a biosensor structure 10 in accordance with some embodiments of the present disclosure, and FIG. 1B is a cross-sectional diagram of the biosensor structure 10 taken along the section line A-A′ in FIG. 1A in accordance with some embodiments of the present disclosure. It should be understood that some elements of the biosensor structure 10 may be omitted in FIG. 1A and FIG. 1B for clarity. In addition, additional features may be added to the biosensor structure 10 in accordance with some embodiments of the present disclosure.

In accordance with the embodiments of the present disclosure, the biosensor structure 10 may be not limited to a particular use. In accordance with some embodiments, the biosensor structure 10 may be used for biological or biochemical analysis. For example, the biosensor structure 10 may be used to measure or analyze a DNA sequence (e.g., next-generation sequencing (NGS)), DNA-DNA hybridization, single nucleotide polymorphisms, protein interactions, peptide interactions, antigen-antibody interactions, protein microarray, liquid biopsy, quantitative polymerase chain reaction (qPCR), glucose monitoring, cholesterol monitoring, and the like.

The biosensor structure 10 may include a substrate 100, an insulating layer 200, and a semiconductor layer 300. The insulating layer 200 may be disposed on the substrate 100, and the semiconductor layer 300 may be disposed on the insulating layer 200. The biosensor structure 10 may include a plurality of wells 300p, and the wells 300p may be disposed in the semiconductor layer 300. In addition, the biosensor structure 10 may include a plurality of gold discs 400, and each of the gold discs 400 may be disposed at the bottom of the respective well 300p.

In accordance with some embodiments, the wells 300p may be arranged in an array. As shown in FIG. 1B, in accordance with some embodiments, the well 300p may penetrate through the semiconductor layer 300 and the gold disc 400 may be disposed on the top surface 200t of the insulating layer 200. In accordance with some embodiments, the semiconductor layer 300 and the gold disc 400 may be in direct contact with the top surface 200t of the insulating layer 200.

In accordance with some embodiments, the substrate 100 may be a holder or a CMOS image sensor. In other words, the substrate 100 may have a detection function itself in accordance with some embodiments. In accordance with some embodiments, the insulating layer 200 may serve as an etch stop layer. Specifically, the insulating layer 200 may serve as the etch stop layer of the etching process for forming the wells 300p. In addition, the well 300p may provide the space for accommodating the solutions and biosamples to be analyzed. The well 300p may serve as the reaction site of the biosensor structure 10. In addition, the gold disc 400 may be used to capture biosamples. The aspect of the biosensor structure 10 with the biosamples applied therein will be described in detail later.

In accordance with some embodiments, the substrate 100 may be an opaque substrate, a transparent substrate or a semi-transparent substrate. In accordance with some embodiments, the substrate 100 may include, but is not limited to, a silicon substrate, a glass substrate, a sapphire substrate, a ceramic substrate, a quartz substrate, a complementary metal-oxide-semiconductor (CMOS) substrate, or a combination thereof. In accordance with some embodiments, the thickness of the substrate 100 may be in a range from 500 micrometers (μm) to 1000 micrometers, but it is not limited thereto.

In accordance with some embodiments, the insulating layer 200 may be transparent or semi-transparent. In accordance with some embodiments, the material of the insulating layer 200 may include, but is not limited to, aluminum oxide, aluminum oxynitride, titanium oxide, titanium oxynitride, silicon oxide, silicon nitride, silicon oxynitride, or a combination thereof. In accordance with some embodiments, the thickness of the insulating layer 200 may be in a range from 30 nanometers (nm) to 10 μm, but it is not limited thereto.

In accordance with some embodiments, the material of the semiconductor layer 300 may include, but is not limited to, silicon, for example, monocrystalline silicon. In accordance with some embodiments, the thickness of the semiconductor layer 300 may be in a range from 100 nm to 1000 μm, but it is not limited thereto. The thickness of the semiconductor layer 300 defines the depth of the well 300p. That is, the thickness of the semiconductor layer 300 may be substantially the same as the depth of the well 300p. In various embodiments, the thickness of the semiconductor layer 300 may be adjusted according to actual needs.

In accordance with some embodiments, the well 300p may have a pillar profile, but it is not limited thereto. In accordance with some embodiments, an aspect ratio (height/width) of the well 300p may be in a range from 2 to 1000. In accordance with some embodiments, the diameter of the well 300p may be in a range from 100 nm to 500 μm, for example, from 100 nm to 1000 nm (e.g., for nanoarray), or from 1 μm to 500 μm (e.g., for microarray), but it is not limited thereto. Furthermore, in accordance with some embodiments, a pitch P1 of the wells 300p (e.g., the distance between the same side of the two adjacent wells 300p) may be in a range from 120 nm to 550 μm, for example, from 120 nm to 1100 nm (e.g., for nanoarray), or from 1.1 μm to 550 μm (e.g., for microarray), but it is not limited thereto.

In accordance with some embodiments, the gold discs 400 are left by a metal-assisted chemical etching (MacEtch) process. Specifically, the MacEtch process may be used to form the wells 300p, the gold discs 400 are used to define the positions of the wells 300p during the MacEtch process, and the gold discs 400 remain at the bottom of the wells 300p (i.e. on the top surface 200t of the insulating layer 200) after the MacEtch process.

In accordance with some embodiments, the thickness T₄₀₀ of the gold disc 400 may be in a range from 10 nm to 60 nm. It should be noted that if the thickness T₄₀₀ of the gold disc 400 is too large (e.g., greater than 60 nm), the optical transparency of the gold disc 400 may be blocked so that the detector structure (not illustrated) below the biosensor structure 10 cannot perform detection. However, in accordance with some embodiments where the detector structure is not disposed below the biosensor structure 10 (for example, disposed above the biosensor structure 10), the thickness T₄₀₀ of the gold disc 400 may be adjusted according to needs. Moreover, in accordance with some embodiments, the diameter D₄₀₀ of the gold disc 400 may be in a range from 100 nm to 500 μm. In addition, the diameter D₄₀₀ of the gold disc 400 can be used to define the diameter of the well 300p. That is, the diameter D₄₀₀ of the gold disc 400 may be substantially the same as the diameter of the well 300p.

In accordance with some embodiments, a silane coating (not illustrated) may be optionally disposed on the sidewalls 300s of the well 300p and the top surface 300t of the semiconductor layer 300. In accordance with some embodiments, the silane coating may include silane having a terminal hydroxyl (—OH) group. The sidewalls 300 and the top surface 300t that are modified with silane having terminal hydroxyl group can reduce the non-specific binding of biosamples SA on the sidewalls 300 and the top surface 300t.

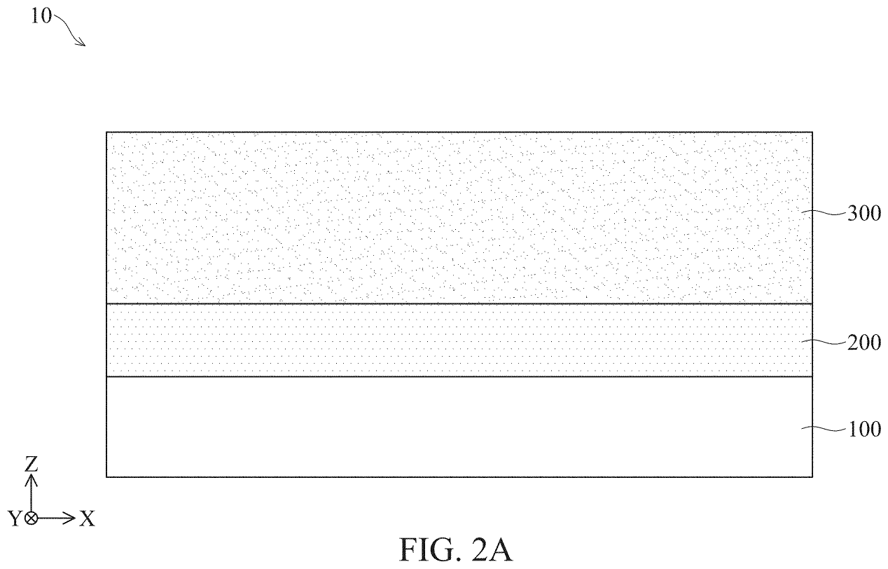

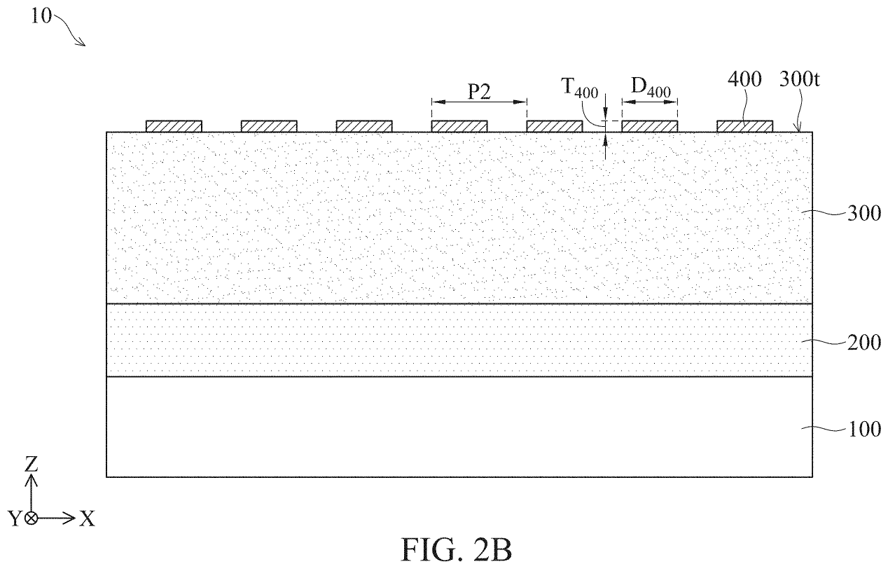

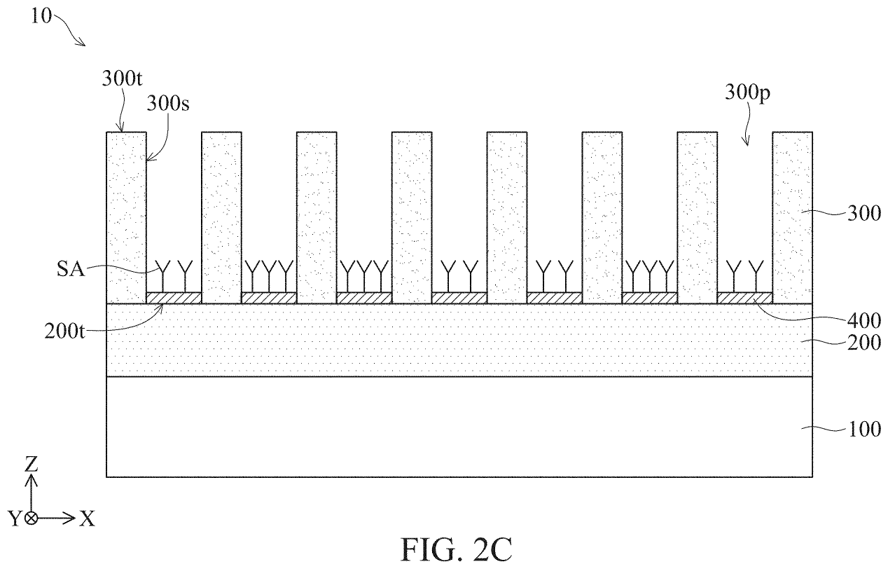

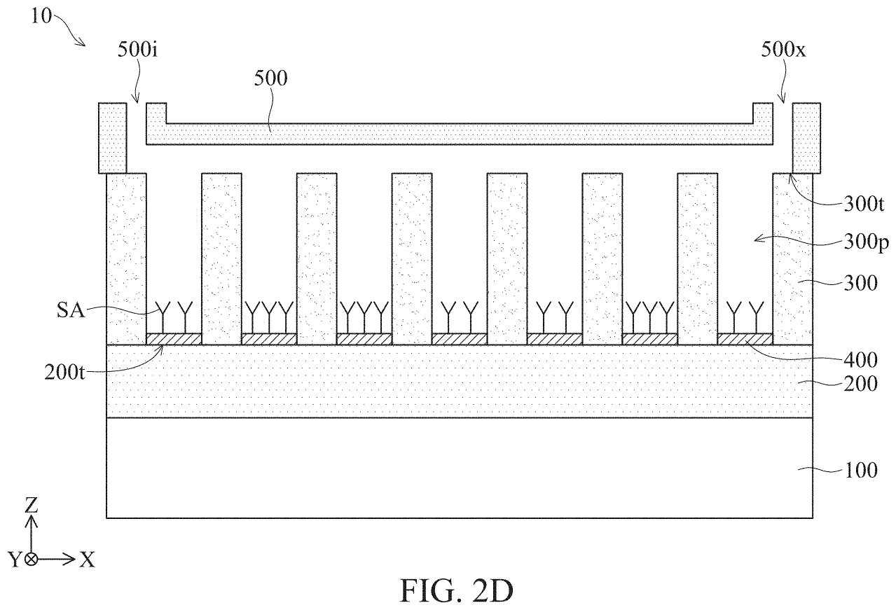

Furthermore, in accordance with some embodiments, the biosensor structure 10 may further include a microfluidic cover 500 (as shown in FIG. 2D) disposed on the semiconductor layer 300. The microfluidic cover 500 may be disposed over the top surface 300t of the semiconductor layer 300. The microfluidic cover 500 may include an inlet 500i and an outlet 500x. The analyte may enter the biosensor structure 10 from the inlet 500i and exit the biosensor structure 10 from the outlet 500x. In accordance with some embodiments, the microfluidic cover 500 may include microfluidic channels disposed thereon or therein. The layout of the microfluidic channels can be designed according to needs.

In accordance with some embodiments, the microfluidic cover 500 may be transparent or semi-transparent. In accordance with some embodiments, the material of the microfluidic cover 500 may include an organic material, an inorganic material, or a combination thereof. For example, the organic material may include epoxy resins, silicone resins (such as polydimethylsiloxane (PDMS)), acrylic resins (such as polymethylmetacrylate (PMMA)), polyimide (PI), polycarbonate (PC), polyethylene terephthalate (PET), perfluoroalkoxy alkane (PFA), other suitable materials or a combination thereof, but it is not limited thereto. For example, the inorganic material may include glass, ceramic, silicon nitride, silicon oxide, sapphire, aluminum oxide, other suitable materials or a combination thereof, but it is not limited thereto.

In addition, in accordance with some embodiments, a biosensor system (not illustrated) may be provided. The biosensor system may include the biosensor structure as described above, and a detector structure for detecting the biosensor structure. In accordance with some embodiments, the detector structure may include, but is not limited to, a photodiode, an optical microscope, a spectrophotometer, or another suitable detector structure. In accordance with some embodiments, a signal processor (not illustrated) may be coupled to the detector structure.

Next, refer to FIGS. 2A-2D, which are cross-sectional diagrams of the biosensor structure 10 during a method for forming the biosensor structure in accordance with some embodiments of the present disclosure. It should be understood that, additional operations may be provided before, during, or after the processes in the method for forming the biosensor structure. In accordance with some embodiments, some of the operations described below may be replaced or omitted.

Referring to FIG. 2A, the substrate 100 may be provided, the insulating layer 200 may be formed on the substrate 100, and then the semiconductor layer 300 may formed on the insulating layer 200.

In accordance with some embodiments, the insulating layer 200 may be formed on the substrate 100 using a chemical vapor deposition (CVD) process, a spin coating process, a printing process, or a combination thereof. The chemical vapor deposition process may include, but is not limited to, a low-pressure chemical vapor deposition (LPCVD) process, a low-temperature chemical vapor deposition (LTCVD) process, a rapid thermal chemical vapor deposition (RTCVD) process, a plasma enhanced chemical vapor deposition (PECVD) process, or an atomic layer deposition (ALD) process. In some embodiments where the substrate 100 is a CMOS substrate (CMOS image sensor), the passivation layer of the CMOS substrate may serve as the insulating layer 200, and there may be no need to form the additional insulating layer 200.

In accordance with some embodiments, the semiconductor layer 300 may be directly bonded on the insulating layer 200. In accordance with some embodiments, the semiconductor layer 300 having the thickness ranging from 500 μm to 1000 μm may be bonded on the insulating layer 200, and then a grinding process may be performed on the semiconductor layer 300 until a desired thickness of the semiconductor layer 300 is achieved, i.e. the desired depth of the well 300p. For example, the thickness of the semiconductor layer 300 may be in a range from 100 nm to 1000 μm, but it is not limited thereto.

Referring to FIG. 2B, the gold discs 400 may be formed on the top surface 300t of the semiconductor layer 300. As described above, the location of the gold discs 400 define the position of the wells 300p that are to be formed in the subsequent etching process. In accordance with some embodiments, the gold disc 400 may be formed using a physical vapor deposition (PVD) process, an electroplating process, an electroless plating process, another suitable process, or a combination thereof. The physical vapor deposition process may include, but is not limited to, a sputtering process, an evaporation process, or a pulsed laser deposition.

As described above, in accordance with some embodiments, the diameter D₄₀₀ of the gold disc 400 may be in a range from 100 nm to 500 μm. The diameter D₄₀₀ of the gold disc 400 can be used to define the diameter of the well 300p. In accordance with some embodiments, the pitch P2 of the gold discs 400 (e.g., the distance between the same side of the two adjacent gold discs 400) may be in a range from 100 nm to 550 μm, for example, from 100 nm to 1100 nm (e.g., for nanoarray), or from 1.1 μm to 550 μm (e.g., for microarray), but it is not limited thereto. In accordance with some embodiments, the thickness T₄₀₀ of the gold disc 400 may be in a range from 10 nm to 60 nm.

Referring to FIG. 2C, the wells 300p may be formed in the semiconductor layer 300 using an etching process, while the gold discs 400 remain at the bottom of the wells 300p. Specifically, the insulating layer 200 may serve as an etching stop layer. The wells 300p may penetrate through the semiconductor layer 300, and the gold discs 400 may be disposed on the top surface 200t of the insulating layer 200 after the etching process. In accordance with some embodiments, the etching process may be a metal-assisted chemical etching (MacEtch) process.

It should be noted that since the insulating layer 200 serves as the etching stop layer, the etching of the wells 300p can stop accurately above the insulating layer 200. Therefore, the bottom surfaces of the wells 300p are substantially flat, and the flat bottom surfaces of the wells 300p provide advantageous biosample loading environment for the biosensor structure 10.

Moreover, the gold disc 400 remaining at the bottom of the well 300p (i.e. on the top surface 200t of the insulating layer 200) can be used to capture biosamples SA. As shown in FIG. 2C, the gold disc 400 may be immobilized with biosamples SA. The biosample SA may be thiolated so that it can easily bind to the gold disc 400. Specifically, in accordance with some embodiments, one end of the biosample SA may be modified with a first functional group, and the first functional group may be thiol group (—SH) that can form Au—S bonding with the gold disc 400 via self-assembly. In accordance with some embodiments, another end of the biosample SA may be modified with a second functional group, and the second functional group may include, but is not limited to, amine group (—NH2), carboxyl group (—COOH), biotin, streptavidin, or a combination thereof.

It should be understood that the second functional group of the biosample SA can be suitably adjusted according to the target that the biosample SA wants to detect (for example, DNA, RNA, protein, antigen, antibody, lipid micelle, biomolecule-coated nanoparticles etc.).

In accordance with some embodiments, the fluorescence signal can be detected when the biosample SA immobilized at the bottom of the well 300p is conjugated to its target. For example, in accordance with some embodiments, through self-assembly of Au—S bonding, the gold discs 400 at the bottom of the wells 300p are modified with the antibody or antigen, and the biosensor structure 10 is subjected to an enzyme-linked immunosorbent assay (ELISA). Specifically, when the dye-labeled antibody is conjugated to the antigen that is immobilized at the bottom of the well 300p, the fluorescence signal can be detected. In accordance with some embodiments, through self-assembly of Au—S bonding, the gold discs 400 at the bottom of the wells 300p are modified with the DNA, and the biosensor structure 10 is subjected to DNA sequencing. Specifically, when the dye-labeled dNTP is conjugated to the DNA template that is immobilized at the bottom of the well 300p, the florescence signal can be detected.

In accordance with some other embodiments, the changing of optical transmittance (or color) of the analyte containing the biosamples SA can be detected when the biosample SA immobilized at the bottom of the well 300p is conjugated to its target. In accordance with some embodiments, the byproduct of the bio-reaction of the biosample SA and its target may decrease the thickness of the gold disc 400, and the optical transmittance of the analyte containing the biosamples SA will change. Accordingly, the bio-reaction of the biosample SA and its target can be detected.

Furthermore, it should be noted that since the gold disc 400 has good performance on capture biosamples SA through self-assembly of gold-sulfur (Au—S) bonding, further modification (e.g., immobilization of anchor molecules etc.) to the bottom of the wells 300p may not be needed.

In accordance with some embodiments, the sidewalls 300s of the well 300p and the top surface 300t of the semiconductor layer 300 may be optionally modified with a silane blocking agent to form the silane coating. In accordance with some embodiments, the silane blocking agent may include a terminal hydroxyl (—OH) group. The sidewalls 300 and the top surface 300t that are modified with silane having terminal hydroxyl group can reduce the non-specific binding of biosamples SA on the sidewalls 300 and the top surface 300t. Therefore, the detection accuracy and efficiency of the biosensor structure 10 can be improved.

Referring to FIG. 2D, the microfluidic cover 500 may be disposed on the semiconductor layer 300. The microfluidic cover 500 may be disposed over the top surface 300t of the semiconductor layer 300. As shown in FIG. 2D, the microfluidic cover 500 may include the inlet 500i and the outlet 500x. The analyte containing the biosmaples SA or the target molecules may enter the biosensor structure 10 from the inlet 500i and exit the biosensor structure 10 from the outlet 500x.

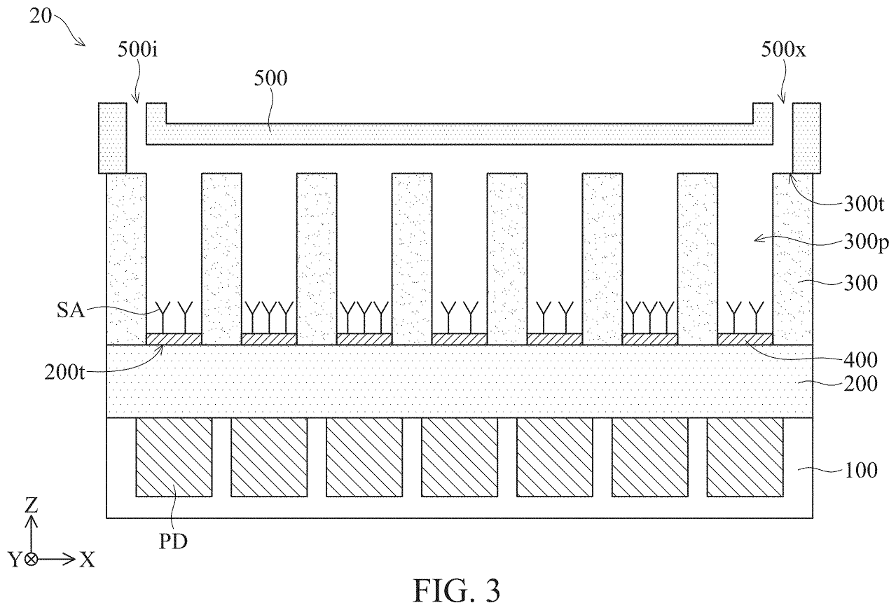

Next, refer to FIG. 3, which is a cross-sectional diagram of the biosensor structure 20 in accordance with some embodiments of the present disclosure. It should be understood that the same or similar components or elements in the context of the descriptions provided above and below are represented by the same or similar reference numerals. The materials, manufacturing methods and functions of these components or elements are the same as or similar to those described above, and thus will not be repeated herein.

As shown in FIG. 3, the substrate 100 of the biosensor structure 20 may be a CMOS substrate (a CMOS image sensor). The CMOS substrate may serve as the detector structure. In accordance with some embodiments, the CMOS substrate may include a plurality of sensing elements disposed therein. For example, the sensing element may include a photodiode PD, or another suitable light sensing component that can convert measured light into current. Specifically, in accordance with some embodiments, the sensing element may include a source and a drain of a metal-oxide-semiconductor (MOS) transistor (not illustrated) that may transfer the current to another component, such as another MOS transistor. The another component may include, but is not limited to, a reset transistor, a current source follower or a row selector for transforming the current into digital signals. In accordance with some embodiments, the signal processor (not illustrated) may be coupled to the CMOS substrate.

To summarize the above, in accordance with some embodiments, the wells of the biosensor structure are formed using a metal-assisted chemical etching (MacEtch) process, and the gold discs used to define the positions of the wells remain at the bottom of the well. The critical dimension of the wells of the biosensor structure formed by such a method can be reduced and the aspect ratio of the wells can be increased. Accordingly, the sensitivity and throughput of the biosensor structure can be improved. In addition, the gold discs have good performance on capture biosamples through self-assembly of gold-sulfur (Au—S) bonding. Therefore, further modification (e.g., immobilization of anchor molecules etc.) to the bottom of the wells where the gold discs are located may not needed.

Although some embodiments of the present disclosure and their advantages have been described in detail, it should be understood that various changes, substitutions and alterations can be made herein without departing from the spirit and scope of the disclosure as defined by the appended claims. For example, it will be readily understood by one of ordinary skill in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A biosensor structure, comprising:
a substrate;
an insulating layer disposed on the substrate;
a semiconductor layer disposed on the insulating layer, wherein a well is disposed in the semiconductor layer; and
a gold disc disposed at bottom of the well.

2. The biosensor structure as claimed in claim 1, wherein the insulating layer comprises aluminum oxide, aluminum oxynitride, titanium oxide, titanium oxynitride, silicon oxide, silicon nitride, silicon oxynitride, or a combination thereof.

3. The biosensor structure as claimed in claim 1, wherein the well penetrates through the semiconductor layer and the gold disc is disposed on a top surface of the insulating layer.

4. The biosensor structure as claimed in claim 1, wherein the substrate comprises a silicon substrate, a glass substrate, a sapphire substrate, a ceramic substrate, a quartz substrate, a complementary metal-oxide-semiconductor (CMOS) substrate, or a combination thereof.

5. The biosensor structure as claimed in claim 1, wherein a thickness of the gold disc is in a range from 10 nanometers to 60 nanometers.

6. The biosensor structure as claimed in claim 1, further comprising a microfluidic cover disposed on the semiconductor layer.

7. The biosensor structure as claimed in claim 1, wherein a diameter of the well is in a range from 100 nanometers to 500 micrometers.

8. The biosensor structure as claimed in claim 1, wherein a sidewall of the well and a top surface of the semiconductor layer are modified with a silane blocking agent.

9. The biosensor structure as claimed in claim 8, wherein the silane blocking agent comprises a terminal hydroxyl group.

10. The biosensor structure as claimed in claim 1, wherein a diameter of the gold disc is in a range from 100 nanometers to 500 micrometers.

11. The biosensor structure as claimed in claim 1, wherein the insulating layer is an etch stop layer.

12. The biosensor structure as claimed in claim 1, wherein the gold disc is left by a metal-assisted chemical etching (MacEtch) process.

13. A biosensor system, comprising:
a biosensor structure, comprising:
a substrate;
an insulating layer disposed on the substrate;
a semiconductor layer disposed on the insulating layer, wherein a well is disposed in the semiconductor layer; and
a gold disc disposed at bottom of the well; and
a detector structure for detecting the biosensor structure.

14. The biosensor system as claimed in claim 13, wherein the gold disc is immobilized with a biosample, one end of the biosample is modified with a first functional group, and the first functional group is thiol group (—SH) that forms Au—S bonding with the gold disc via self-assembly.

15. The biosensor system as claimed in claim 14, wherein another end of the biosample is modified with a second functional group, and the second functional group comprises amine group (—NH₂), carboxyl group (—COOH), biotin, streptavidin, or a combination thereof.

16. The biosensor system as claimed in claim 13, further comprising a signal processor coupled to the detector structure.

17. A method for forming a biosensor structure, comprising:
providing a substrate;
forming an insulating layer on the substrate;
forming a semiconductor layer disposed on the insulating layer;
forming a gold disc on a top surface of the semiconductor layer, wherein a location of the gold disc defines a position of a well; and
forming the well in the semiconductor layer using an etching process, while the gold disc remains at bottom of the well.

18. The method for forming a biosensor structure as claimed in claim 17, wherein the well penetrates through the semiconductor layer, and the gold disc is disposed on a top surface of the insulating layer after the etching process.

19. The method for forming a biosensor structure as claimed in claim 17, wherein the etching process is a metal-assisted chemical etching (MacEtch) process.

20. The method for forming a biosensor structure as claimed in claim 17, wherein the insulating layer is an etch stop layer.
